(19) United States
(12) Patent Application Publication
(10) Pub. No.: US 2018/0338614 A1
(43) Pub. Date: Nov. 29, 2018

(54) RACK MOUNTING SYSTEM

(71) Applicants: KING SLIDE WORKS CO., LTD., Kaohsiung City (TW); KING SLIDE TECHNOLOGY CO.,LTD., Kaohsiung City (TW)

(72) Inventors: Ken-Ching Chen, Kaohsiung City (TW); Shun-Ho Yang, Kaohsiung City (TW); Chien-Li Huang, Kaohsiung City (TW); Yao-Tsung Chen, Kaohsiung City (TW); Chun-Chiang Wang, Kaohsiung City (TW)

(21) Appl. No.: 15/821,854

(22) Filed: Nov. 24, 2017

(30) Foreign Application Priority Data
May 26, 2017 (TW) 106118005

(51) Int. Cl. A47B 88/407; A47B 88/423

(52) U.S. Cl. CPC A47B 88/407; H05K 7/1489; A47B 88/423

(57) ABSTRACT

A rack mounting system comprises a mounting mechanism, a first connecting assembly and a second connecting assembly. The mounting mechanism is configured to be detachably mounted to a first side of a rack, and movable relative to the first side of the rack. The first connecting assembly is configured to be detachably mounted to a second side of the rack. The second connecting assembly is connected to the mounting mechanism. Wherein, the first connecting assembly and the second connecting assembly are configured to carry a first chassis with a first chassis width when the mounting mechanism is moved to a first position relative to the first side of the rack.

### BACKGROUND OF THE INVENTION

### 1. Field of the Invention

The present invention relates to a rack mounting system, and more particularly, to a rack mounting system capable mounting chassis with different width to a rack.

### 2. Description of the Prior Art

Generally, a rack has a first side and a second side defining a rack width. A rack mounting system comprises at least one pair of connecting assemblies, such as rail members, respectively mounted at two sides of the rack in order to mount a chassis to the rack.

The current rack mounting system can only to be applied to a rack and a chassis comply with the same specification. Once specifications or sizes of the rack and the chassis do not match, the chassis cannot be mounted to the rack.

With rapid development of information technology, dimensions (such as a width dimension) of a chassis are getting bigger to accommodate more electronic apparatuses or related components. U.S. Pat. No. 9,131,769 B2 discloses such specification for the chassis with a greater width. However, when the specifications or sizes of the rack and chassis do not match, the solution disclosed in the aforementioned invention is to install a plurality of posts at inner regions of the rack, in order to reduce the original rack width of the rack. However, according to such design, only the chassis complied with one predetermined specification can be mounted to the width-reduced rack.

### SUMMARY OF THE INVENTION

The present invention provides a rack mounting system capable mounting chassis with different width to a rack.

According to an embodiment of the present invention, a rack mounting system is applicable to a rack. The rack mounting system comprises a mounting mechanism, a first connecting assembly and a second connecting assembly. The mounting mechanism is configured to be detachably mounted to a first side of the rack, and movable relative to the first side of the rack. The first connecting assembly is configured to be detachably mounted to a second side of the rack. The second connecting assembly is connected to the mounting mechanism. Wherein, the first connecting assembly and the second connecting assembly are configured to carry a first chassis with a first chassis width when the mounting mechanism is moved to a first position relative to the first side of the rack.

Preferably, the first connecting assembly has a first connecting width and the second connecting assembly has a second connecting width. The mounting mechanism inwardly extends a first mounting length from the first side of the rack when the mounting mechanism is moved to the first position relative to the first side of the rack. The first mounting length is greater than the first connecting width and the second connecting width.

Preferably, the first connecting assembly and the second connecting assembly are configured to carry a second chassis with a second chassis width when the mounting mechanism is moved to an extension position from the first position relative to the first side of the rack. The second chassis width is different from the first chassis width.

Preferably, the first connecting assembly comprises a first fixed rail, and the second connecting assembly comprises a second fixed rail. The first fixed rail and the second fixed rail are configured to fixedly mount the first chassis with the first chassis width into the rack.

Preferably, the first connecting assembly comprises a first fixed rail and a first movable rail, and the second connecting assembly comprises a second fixed rail and a second movable rail. The first movable rail and the second movable rail allow the first chassis with the first chassis width to be pulled out of the rack.

According to another embodiment of the present invention, a rack mounting system comprises a first connecting assembly, a second connecting assembly and a mounting mechanism. The first connecting assembly is configured to be connected to a first side of a chassis. The second connecting assembly is configured to be connected to a second side of the chassis. The mounting mechanism is connected to the second connecting assembly. Wherein, when the mounting mechanism is mounted to a first side of a first rack and the first connecting assembly is mounted to a second side of the first rack, the mounting mechanism is configured to inwardly extend a first mounting length from the first side of the first rack in order to mount the chassis to the first rack. The first rack has a first rack width. Wherein, when the mounting mechanism is mounted to a first side of a second rack and the first connecting assembly is mounted to a second side of the second rack, the mounting mechanism is configured to inwardly extend a second mounting length from the first side of the second rack in order to mount the chassis to the second rack. The second rack has a second rack width different from the first rack width.

Preferably, the first connecting assembly has a first connecting width and the second connecting assembly has a second connecting width. The first mounting length is greater than the first connecting width and the second connecting width. The second mounting length is greater than the first connecting width and the second connecting width.

Preferably, the first connecting assembly comprises a first fixed rail, and the second connecting assembly comprises a second fixed rail. The first fixed rail and the second fixed rail are configured to fixedly mount the chassis into the first rack or the second rack.

Preferably, the first connecting assembly comprises a first fixed rail and a first movable rail, and the second connecting assembly comprises a second fixed rail and a second movable rail. The first movable rail and the second movable rail allow the chassis to be pulled out of the first rack or the second rack.

According to another embodiment of the present invention, a rack system comprises a rack, a mounting mechanism, a first connecting assembly and a second connecting assembly. The rack has a first side and a second side. The mounting mechanism is detachably mounted to the first side of the rack. The first connecting assembly is detachably mounted to the second side of the rack. The second connecting assembly is connected to the mounting mechanism. Wherein, the first connecting assembly and the second connecting assembly are configured to mount a first chassis with a first chassis width to the rack when the mounting mechanism is located at a first position relative to the first side of the rack. Wherein, the first connecting assembly and the second connecting assembly are configured to mount a second chassis with a second chassis width to the rack when the mounting mechanism is located at an extension position relative to the first side of the rack. The extension position is different from the first position. The second chassis width is different from the first chassis width.

Preferably, the first connecting assembly has a first connecting width. The second connecting assembly has a second connecting width. The mounting mechanism inwardly extends a first mounting length from the first side of the rack when the mounting mechanism is located at the first position relative to the first side of the rack. The first mounting length is greater than the first connecting width and the second connecting width.

Preferably, the first connecting assembly comprises a first fixed rail, and the second connecting assembly comprises a second fixed rail. The first fixed rail and the second fixed rail are configured to fixedly mount the first chassis or the second chassis into the rack.

Preferably, the first connecting assembly comprises a first fixed rail and a first movable rail, and the second connecting assembly comprises a second fixed rail and a second movable rail. The first movable rail and the second movable rail allow the first chassis to be pulled out of the first rack.

Preferably, the first connecting assembly comprises a first fixed rail and a first movable rail, and the second connecting assembly comprises a second fixed rail and a second movable rail. The first movable rail and the second movable rail allow the second chassis to be pulled out of the rack.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a portion of a first chassis mounted to one side of a first rack according to an embodiment of the present invention.

FIG. 2 is a diagram showing the first chassis mounted to the first rack according to an embodiment of the present invention.

FIG. 3 is a diagram showing a portion of a second chassis mounted to one side of the first rack according to an embodiment of the present invention.

FIG. 4 is a diagram showing the second chassis mounted to the first rack according to an embodiment of the present invention.

FIG. 5 is a diagram showing the first chassis being pulled out of the rack according to an embodiment of the present invention.

FIG. 6 is a diagram showing the first chassis mounted to a second rack according to an embodiment of the present invention.

### DETAILED DESCRIPTION

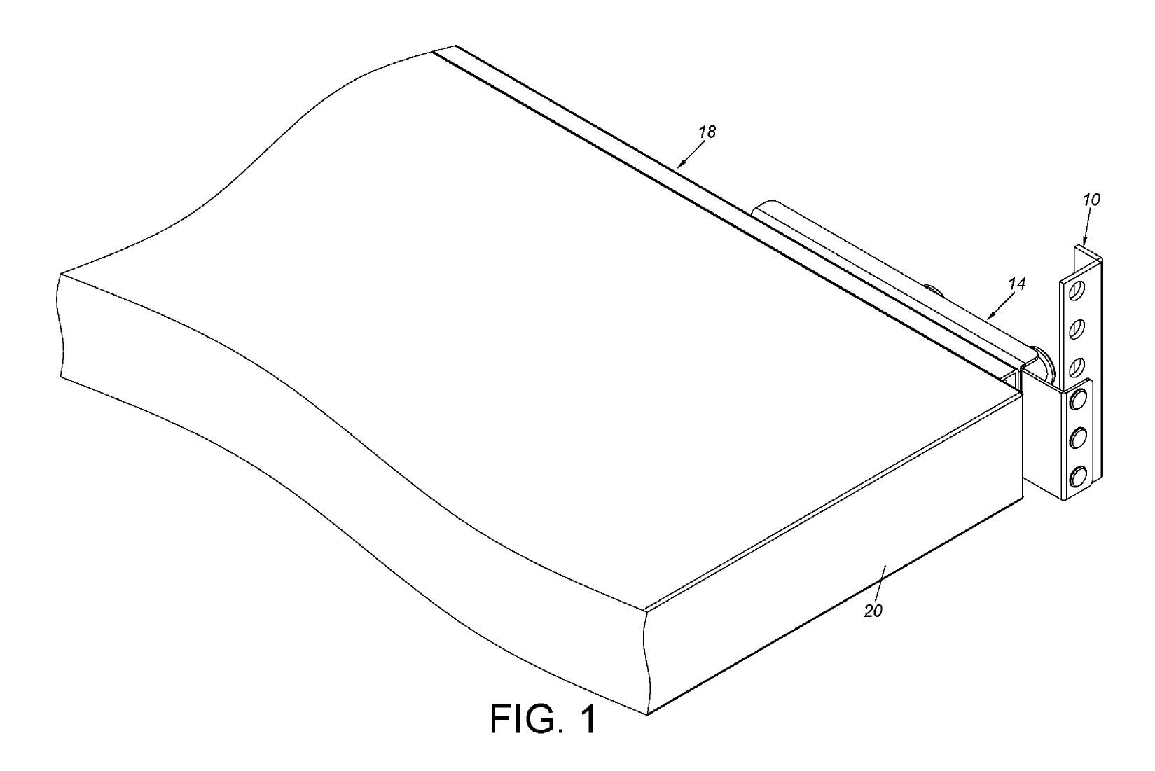

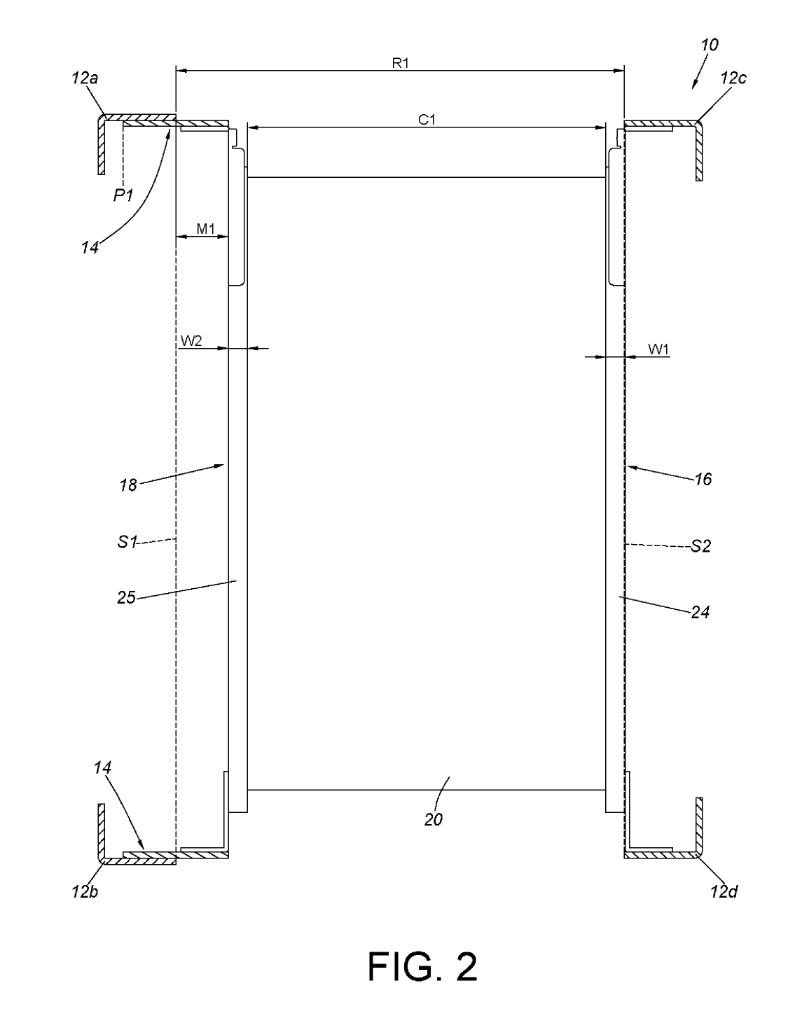

As shown in FIG. 1 and FIG. 2, a rack mounting system is applicable to a first rack 10. The first rack 10 has a plurality of posts, such as a first post 12a, a second post 12b, a third post 12c and a fourth post 12d. Wherein, the first post 12a and the second post 12b are defined as a first side S1 of the first rack 10, the third post 12c and the fourth post 12d are defined as a second side S2 of the first rack 10, and a first rack width R1 is defined between the first side S1 and the second side S2 of the first rack 10.

The rack mounting system comprises a mounting mechanism 14, a first connecting assembly 16 and a second connecting assembly 18. Wherein, the mounting mechanism 14 is detachably mounted to one of the first side S1 and the second side S2 of the first rack 10. In the present embodiment, the mounting mechanism 14 comprises two separated components respectively detachably mounted to the first post 12a and the second post 12b of the first rack 10. That is, the mounting mechanism 14 is detachably mounted to the first side S1 of the first rack 10. In another embodiment, the mounting mechanism 14 can be a single component detachably mounted to the first post 12a and the second post 12b of the first rack 10, but the present invention is not limited thereto. The first connecting assembly 16 is detachably mounted to the other one of the first side S1 and the second side S2 of the first rack 10. In the present embodiment, the first connecting assembly 16 is detachably mounted to the second side S2 of the first rack 10. In addition, the second connecting assembly 18 is connected to the mounting mechanism 14. A first chassis width C1 is defined between the first connecting assembly 16 and the second connecting assembly 18. A first chassis 20 with the first chassis width C1 can be mounted to the first connecting assembly 16 and the second connecting assembly 18. For example, the first connecting assembly 16 can be connected to a first side of the first chassis 20, and the second connecting assembly 18 can be connected to a second side of the first chassis 20.

Preferably, the mounting mechanism 14 inwardly extends a first mounting length M1 relative to the first side S1 of the first rack 10. The first connecting assembly 16 has a first connecting width W1. The second connecting assembly 18 has a second connecting width W2. The first mounting length M1 is greater than the first connecting width W1 and the second connecting width W2.

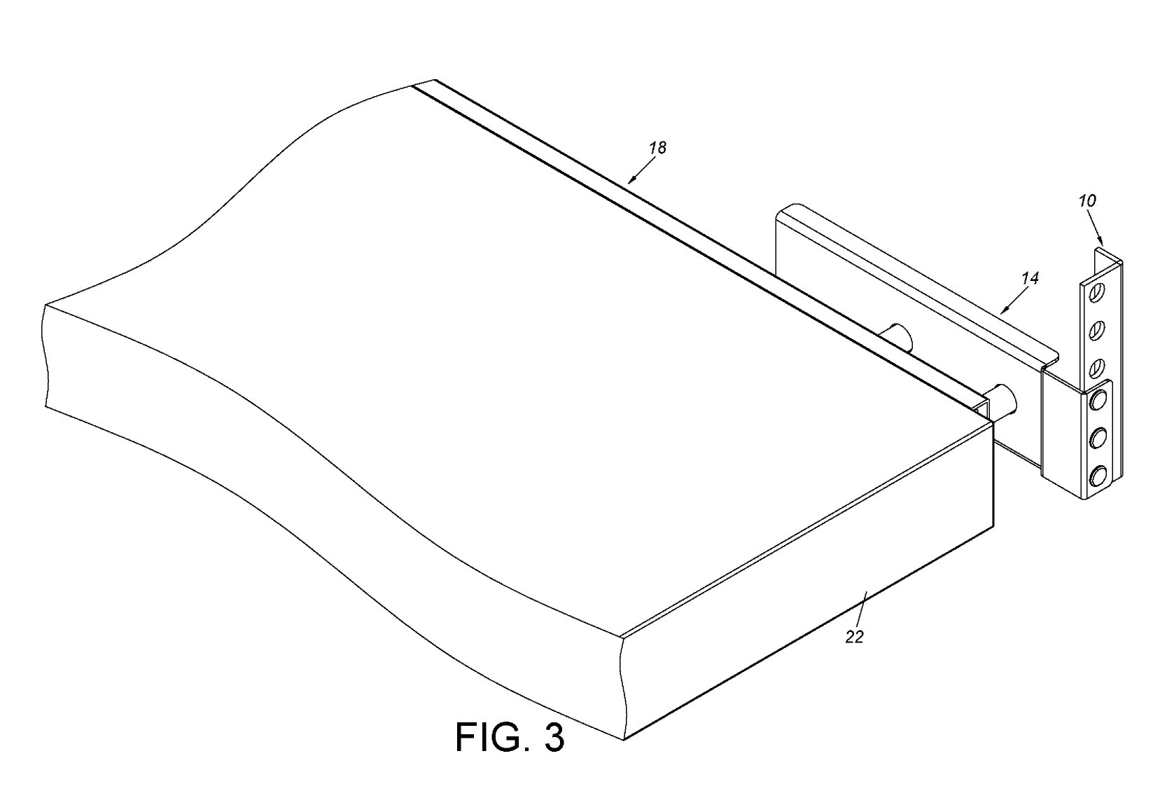

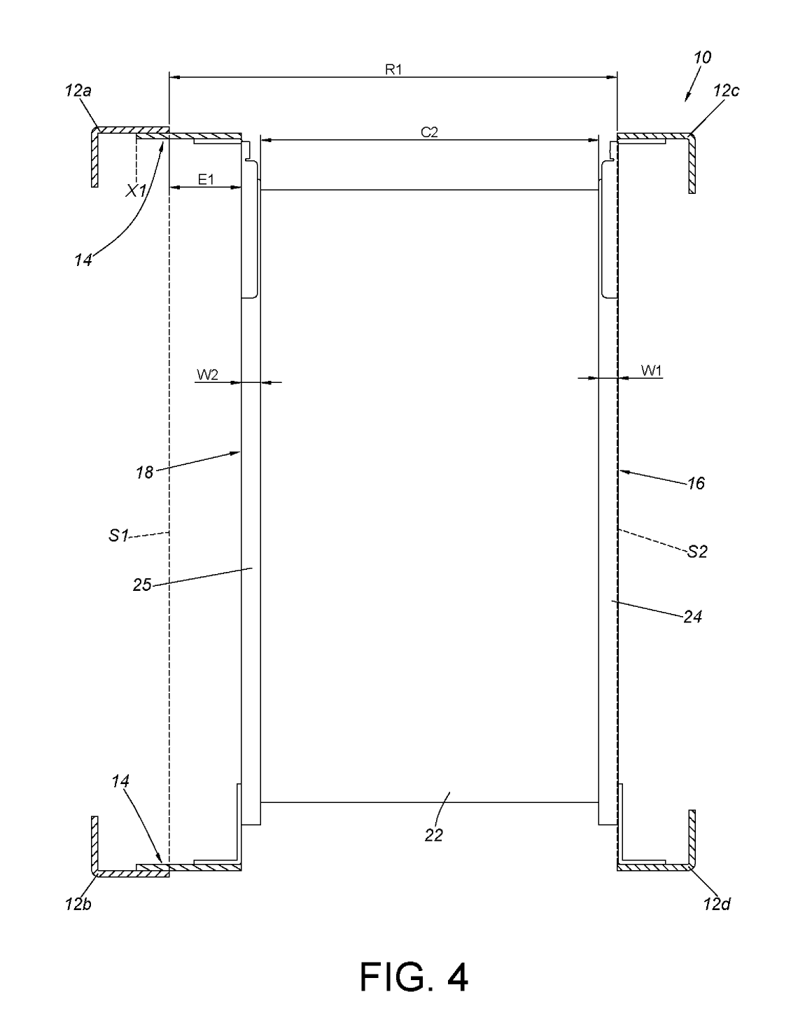

Please refer to FIG. 2 to FIG. 4. Preferably, the mounting mechanism 14 (for ease of explanation, structure and adjusting mechanism of the mounting mechanism 14 are simplified in FIG. 2 and FIG. 4) can be adjusted to move from a first position P1 to an extension position X1, such that the mounting mechanism 14 inwardly extends an extension length E1 from the first side S1 of the first rack 10 for forming a second chassis width C2 between the first connecting assembly 16 and the second connecting assembly 18, in order to mount a second chassis 22 with the second chassis width C2 to the first connecting assembly 16 and the second connecting assembly 18. In another embodiment, the mounting mechanism 14 can be further adjust to mount a chassis with a different chassis width to the first rack 10.

Therefore, the mounting mechanism 14 allows the first chassis 20 with the first chassis width C1 and the second chassis 22 with the second chassis width C2 to be mounted to the first rack 10 with the first rack width R1.

Preferably, the first connecting assembly 16 comprises a first fixed rail 24, and the second connecting assembly 18 comprises a second fixed rail 25. The first fixed rail 24 and the second fixed rail 25 are configured to fixedly mount the first chassis 20 to into the first rack 10. Wherein, specifications of the first fixed rail 24 and the second fixed rail 25 can be identical or different, the present invention is not limited thereto.

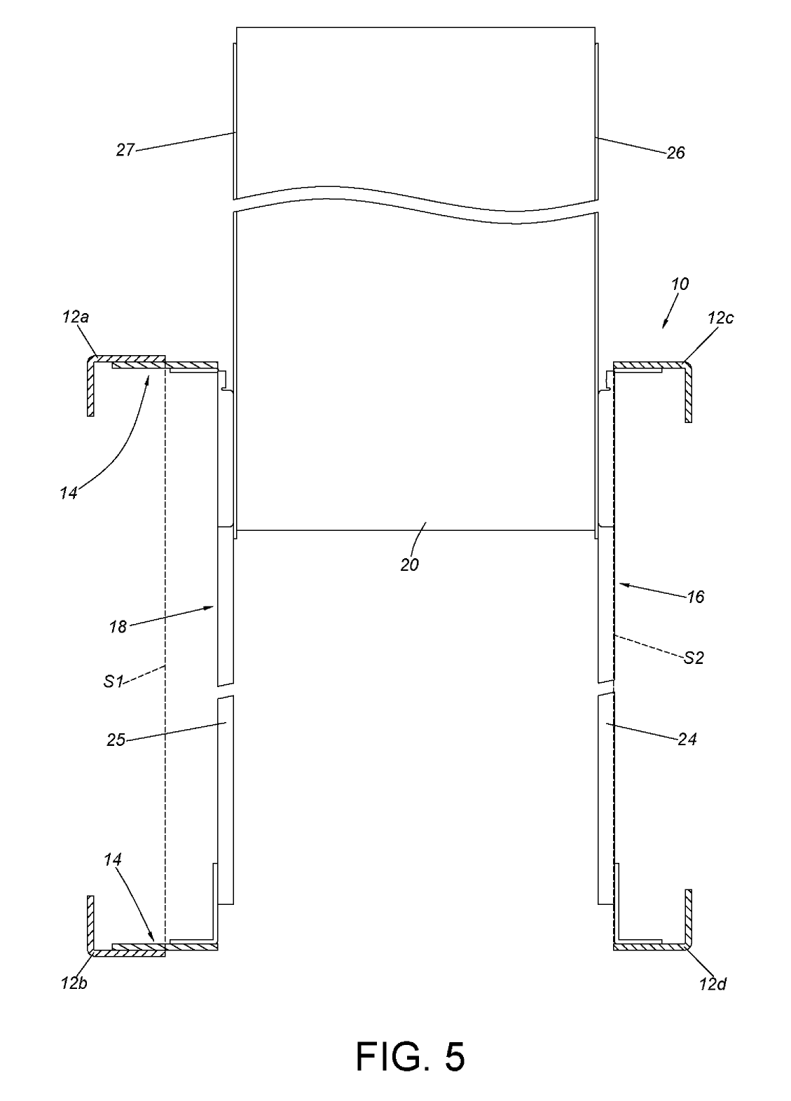

Preferably, as shown in FIG. 5, the first connecting assembly 16 comprises the first fixed rail 24 and a first movable rail 26, and the second connecting assembly 18 comprises the second fixed rail 25 and a second movable rail 27. The first movable rail 26 and the second movable rail 27 allow the first chassis 20 to be pulled out of the first rack 10. Wherein, specifications of rails of the first connecting assembly 16 and the second connecting assembly 18 can be identical or different, the present invention is not limited thereto.

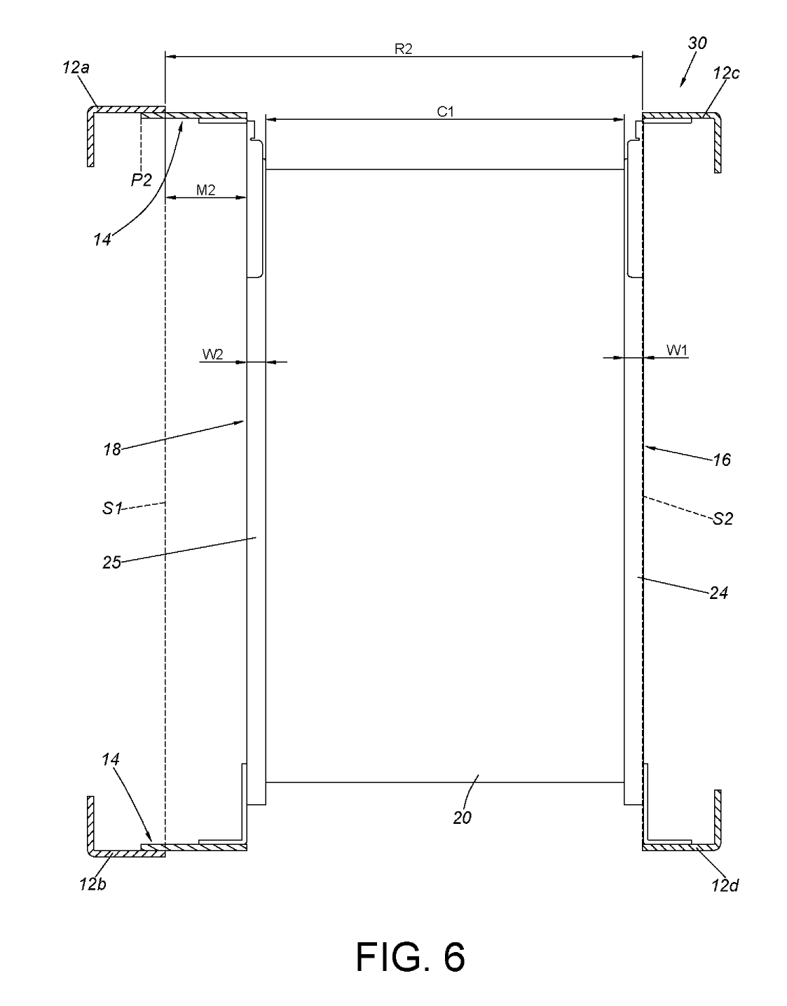

Please refer to FIG. 6. Preferably, the rack mounting system can be also applied to a second rack 30. The second rack 30 has a second rack width R2 different from the first rack width R1 of the first rack 10. The mounting mechanism 14 can be adjusted to move to a second position P2 relative to a first side S1 of the second rack 30, such that the mounting mechanism 14 inwardly extends a second mounting length M2 (different from the first mounting length M1) from the first side S1 of the second rack 30 for forming the first chassis width C1 between the first connecting assembly 16 and the second connecting assembly 18, in order to mount the first chassis 20 with the first chassis width C1 to the first connecting assembly 16 and the second connecting assembly 18. The second mounting length M2 is greater than the first connecting width W1 and the second connecting width W2.

Therefore, the first chassis 20 with the first chassis width C1 can be mounted to the first rack 10 with the first rack width R1 as shown in FIG. 2. Moreover, the first chassis 20 with the first chassis width C1 can also be mounted to the second rack 30 with the second rack width R2 as shown in FIG. 6.

According to the aforementioned illustration, the present invention is characterized in that: when the mounting mechanism 14 inwardly extends the first mounting length Ml relative to the first rack 10, the first chassis 20 with the first chassis width C1 can be mounted to the first rack 10 with the first rack width R1; and when the mounting mechanism 14 is adjusted to inwardly extend the second mounting length M2 relative to the second rack 30, the first chassis 20 with the first chassis width C1 can be mounted to the second rack 30 with the second rack width R2.

In another embodiment, the present invention is characterized in that: when the mounting mechanism 14 of the connecting assembly inwardly extends the first mounting length M1 relative to the first rack 10, the first chassis 20 with the first chassis width C1 can be mounted to the first rack 10 with the first rack width R1; and when the mounting mechanism 14 is adjusted to inwardly extends the extension length E1 relative to the first rack 10, the second chassis 22 with the second chassis width C2 can be mounted to the first rack 10 with the first rack width R1.

Those skilled in the art will readily observe that numerous modifications and alterations of the device and method may be made while retaining the teachings of the invention. Accordingly, the above disclosure should be construed as limited only by the metes and bounds of the appended claims.

what is claimed is:

1. A rack mounting system, applicable to a rack, the rack mounting system comprising:
a mounting mechanism configured to be detachably mounted to a first side of the rack, and movable relative to the first side of the rack;
a first connecting assembly configured to be detachably mounted to a second side of the rack; and
a second connecting assembly connected to the mounting mechanism;
wherein the first connecting assembly and the second connecting assembly are configured to carry a first chassis with a first chassis width when the mounting mechanism is moved to a first position relative to the first side of the rack.

2. The rack mounting system of claim 1, wherein the first connecting assembly has a first connecting width, the second connecting assembly has a second connecting width, wherein the mounting mechanism inwardly extends a first mounting length from the first side of the rack when the mounting mechanism is moved to the first position relative to the first side of the rack, the first mounting length is greater than the first connecting width and the second connecting width.

3. The rack mounting system of claim 1, wherein the first connecting assembly and the second connecting assembly are configured to carry a second chassis with a second chassis width when the mounting mechanism is moved to an extension position from the first position relative to the first side of the rack, the second chassis width is different from the first chassis width.

4. The rack mounting system of claim 1, wherein the first connecting assembly comprises a first fixed rail, and the second connecting assembly comprises a second fixed rail, the first fixed rail and the second fixed rail are configured to fixedly mount the first chassis with the first chassis width into the rack.

5. The rack mounting system of claim 1, wherein the first connecting assembly comprises a first fixed rail and a first movable rail, and the second connecting assembly comprises a second fixed rail and a second movable rail, the first movable rail and the second movable rail allow the first chassis with the first chassis width to be pulled out of the first rack.

6. A rack mounting system, comprising:
a first connecting assembly configured to be connected to a first side of a chassis;
a second connecting assembly configured to be connected to a second side of the chassis; and
a mounting mechanism connected to the second connecting assembly;
wherein when the mounting mechanism is mounted to a first side of a first rack and the first connecting assembly is mounted to a second side of the first rack, the mounting mechanism is configured to inwardly extend a first mounting length from the first side of the first rack in order to mount the chassis to the first rack, the first rack has a first rack width;
wherein when the mounting mechanism is mounted to a first side of a second rack and the first connecting assembly is mounted to a second side of the second rack, the mounting mechanism is configured to inwardly extend a second mounting length from the first side of the second rack in order to mount the chassis to the second rack, the second rack has a second rack width different from the first rack width.

7. The rack mounting system of claim 6, wherein the first connecting assembly has a first connecting width, the second connecting assembly has a second connecting width, the first mounting length is greater than the first connecting width and the second connecting width, the second mounting length is greater than the first connecting width and the second connecting width.

8. The rack mounting system of claim 6, wherein the first connecting assembly comprises a first fixed rail, and the second connecting assembly comprises a second fixed rail, the first fixed rail and the second fixed rail are configured to fixedly mount the chassis into the first rack or the second rack.

9. The rack mounting system of claim 6, wherein the first connecting assembly comprises a first fixed rail and a first movable rail, and the second connecting assembly comprises a second fixed rail and a second movable rail, the first movable rail and the second movable rail allow the chassis to be pulled out of the first rack or the second rack.

10. A rack system, comprising:
a rack having a first side and a second side;
a mounting mechanism detachably mount to the first side of the rack;
a first connecting assembly detachably mount to the second side of the rack; and
a second connecting assembly connected to the mounting mechanism;
wherein the first connecting assembly and the second connecting assembly are configured to mount a first chassis with a first chassis width to the rack when the mounting mechanism is located at a first position relative to the first side of the rack;
wherein the first connecting assembly and the second connecting assembly are configured to mount a second chassis with a second chassis width to the rack when the mounting mechanism is located at an extension position relative to the first side of the rack, the extension position is different from the first position, the second chassis width is different from the first chassis width.

11. The rack system of claim 10, wherein the first connecting assembly has a first connecting width, the second connecting assembly has a second connecting width; wherein the mounting mechanism inwardly extends a first mounting length from the first side of the rack when the mounting mechanism is located at the first position relative to the first side of the rack, the first mounting length is greater than the first connecting width and the second connecting width.

12. The rack system of claim 10, wherein the first connecting assembly comprises a first fixed rail, and the second connecting assembly comprises a second fixed rail, the first fixed rail and the second fixed rail are configured to fixedly mount the first chassis or the second chassis into the rack.

13. The rack system of claim 10, wherein the first connecting assembly comprises a first fixed rail and a first movable rail, and the second connecting assembly comprises a second fixed rail and a second movable rail, the first movable rail and the second movable rail allow the first chassis to be pulled out of the first rack.

14. The rack system of claim 10, wherein the first connecting assembly comprises a first fixed rail and a first movable rail, and the second connecting assembly comprises a second fixed rail and a second movable rail, the first movable rail and the second movable rail allow the second chassis to be pulled out of the rack.
